(19) United States
(12) Patent Application Publication
(10) Pub. No.: US 2026/0262456 A1
(43) Pub. Date: Sep. 3, 2026

(54) SUBSTRATE PROCESSING METHOD

(71) Applicant: SCREEN Holdings Co., Ltd., Kyoto (JP)

(72) Inventors: Linh Da HO, Kyoto (JP); Masaki INABA, Kyoto (JP)

(21) Appl. No.: 18/879,868

(22) PCT Filed: May 30, 2023
(86) PCT No.: PCT/JP2023/020090

§ 371 Date: Dec. 30, 2024

(30) Foreign Application Priority Data
Jun. 29, 2022 (JP) 2022-105007

(51) Int. Cl. H10P 50/64; G03F 7/00; G03F 7/40; G03F 7/42; H10P 95/70

(52) U.S. Cl. CPC H10P 50/642; G03F 7/0035; G03F 7/405; G03F 7/422; H10P 95/70

(57) ABSTRACT

A substrate processing method includes the steps of selectively arranging an organic catalyst for promotion of a redox reaction in a region to be etched on a surface of a semiconductor substrate, supplying an etching solution that contains a corrosive agent and an oxidizing agent onto the surface of the semiconductor substrate on which the organic catalyst is arranged, and after performing desired etching on the semiconductor substrate, removing the organic catalyst. The organic catalyst preferably meets the following condition: E_{O}>E_{A}>E_{S}, where E_{S} represents a reduction potential of the semiconductor substrate, E_{A} represents a reduction potential of the organic catalyst, and E_{O} represents a reduction potential of the oxidizing agent. The organic catalyst preferably includes one or two or more types of a redox organic compound and a redox organic polymer.

### RELATED APPLICATION

The present application is a 35 U.S.C. §§ 371 national stage application of International Application No. PCT/JP2023/020090 filed May 30, 2023, which claims priority to Japanese Patent Application No. 2022-105007, filed Jun. 29, 2022, the content of which is incorporated herein by reference in its entirety.

### TECHNICAL FIELD

The present invention relates to a substrate processing method of processing a substrate. In the present invention, the substrate to be processed is a semiconductor substrate, and the content of processing is etching.

### BACKGROUND ART

Patent Literature 1 below discloses, as a method of forming a hole and/or trench in a semiconductor substrate, a technique in which a protective film with a pattern shape that depends on the shape of the hole and/or trench to be formed is formed and the protective film is used as a mask and an etching solution is used to etch the semiconductor substrate by a MacEtch (Metal-assisted Chemical Etching) method.

### CITATION LIST

### Patent Literature

Patent Literature 1: Japanese Patent Application Publication No. 2019-140225

### SUMMARY OF INVENTION

### Technical Problem

Since the MacEtch method disclosed in Patent Literature 1 uses noble metal as a catalyst, there may be a risk of metal contamination of the semiconductor substrate. In addition, the use of noble metal may cause a cost increase, and further the patterning of noble metal and the removal of noble metal after etching may also increase processing costs.

Hence, a preferred embodiment of the present invention provides a substrate processing method in which a semiconductor substrate can be etched with reduced risk of metal contamination and reduced cost.

### Solution to Problem

(1) A preferred embodiment of the present invention provides a substrate processing method including the steps of selectively arranging an organic catalyst for promotion of a redox reaction in a region to be etched on a surface of the semiconductor substrate, supplying an etching solution that contains a corrosive agent and an oxidizing agent onto the surface of the semiconductor substrate on which the organic catalyst is arranged, and after performing desired etching on the semiconductor substrate, removing the organic catalyst from the semiconductor substrate.

When the etching solution is supplied onto the region in which the organic catalyst is arranged, the exchange of electrons between the etching solution and the semiconductor substrate is promoted via the organic catalyst to result in rapid progress of the redox reaction. This results in rapid progress of an etching reaction in which the surface of the semiconductor substrate is oxidized to form an oxidized film, which is then corroded by the corrosive agent. Such a rapid etching reaction selectively occurs in the region in which the organic catalyst is arranged, whereby the semiconductor substrate can be processed from the surface according to a pattern of arrangement of the organic catalyst.

Organic catalyst, also referred to as an organic compound catalyst, shows a catalytic action with no metal element. It can therefore have reduced risk of metal contamination and reduced cost as compared with the case where a noble metal catalyst is used. It is thus possible to provide a substrate processing method in which a semiconductor substrate can be etched with reduced risk of metal contamination and reduced cost.

(2) In a preferred embodiment of the present invention, the organic catalyst meets the following condition: E_{O}>E_{A}>E_{S}, where E_{S} represents a reduction potential of the semiconductor substrate, E_{A} represents a reduction potential of the organic catalyst, and E_{O} represents a reduction potential of the oxidizing agent.

In accordance with the substrate processing method, since the organic catalyst that is arranged on the surface of the semiconductor substrate has an electron transfer feature comparable to that of a noble metal catalyst (Ag, Au, etc.), the semiconductor substrate can be processed rapidly through the etching reaction.

(3) In a preferred embodiment of the present invention, the organic catalyst includes one or two or more types of a redox organic compound and a redox organic polymer. A redox organic compound and a redox organic polymer have reversible and fast electron transfer ability and thereby have a catalytic action comparable to that of a noble metal catalyst.

(4) In a preferred embodiment of the present invention, the redox organic compound contains one or a combination of two or more selected from the redox organic compound group consisting of 2,2,6,6-tetramethylpiperidinyloxyl (TEMPO), 2,5-di-tert-butyl-1,4-bis(2-methoxyethoxy)benzene (DBBB), N-ethylphenothiazine (EPT), and 3,7-bis(trifluoromethyl)-N-ethylphenothiazine (BCF3EPT), and derivatives thereof. Also, the redox organic polymer contains one or a combination of two or more selected from the redox organic polymer group consisting of TEMPO polymer, Poly(2,2,6,6-tetramethylpiperidinyloxy-4-vinylmethacrylate) (PTMA), Poly(3,4-ethylenedioxythiophene) (PEDOT), and Poly(3-vinyl-N-methylphenothiazine) (PVMPT), and derivatives thereof.

(5) In a preferred embodiment of the present invention, the organic catalyst can employ a TEMPO derivative that is represented by the following chemical formula:

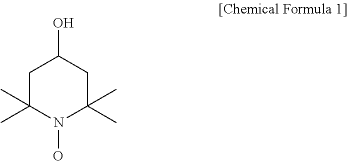

(6) In a preferred embodiment of the present invention, the etching solution contains one or more of dissolved oxygen (O₂), ozone (O₃), hydrogen peroxide (H₂O₂), nitric acid (HNO₃), sodium persulfate (Na₂S₂O₈), and potassium persulfate (K₂S₂O₈) as the oxidizing agent, and one or more of hydrogen fluoride (HF), buffered hydrofluoric acid (BHF), ammonia, sulfuric acid, hydrochloric acid, and citric acid as the corrosive agent.

(7) In a preferred embodiment of the present invention, the semiconductor substrate is a silicon (Si) substrate, a silicon carbide (SiC) substrate, a germanium (Ge) substrate, or a III-V compound semiconductor substrate. Examples of the III-V compound semiconductor substrate include a gallium arsenide (GaAs) compound semiconductor substrate, an indium phosphorus (InP) compound semiconductor substrate, a gallium phosphorus (GaP) compound semiconductor substrate, and the like.

(8) In a preferred embodiment of the present invention, the step of arranging the organic catalyst includes the steps of applying a photolithography resin composition onto the surface of the semiconductor substrate to form an applied film, selectively exposing the applied film that is applied on the surface of the semiconductor substrate depending on a position at which the organic catalyst is to be arranged, developing the exposed applied film to obtain, on the surface of the semiconductor substrate, a patterned film that has an opening portion at the position at which the organic catalyst is to be arranged, and arranging the organic catalyst in the opening portion.

Employing a photolithography technique in the step of arranging the organic catalyst allows a finely patterned film to be formed in which the position at which the organic catalyst is to be arranged is opened. The finely patterned film can then be utilized to arrange the organic catalyst accurately and precisely in a region to be etched on the surface of the semiconductor substrate.

“Arranging the organic catalyst in the opening portion” means arranging the organic catalyst such as to act on the surface of the semiconductor substrate exposed within the opening portion. In short, the organic catalyst is arranged to be in contact with the surface of the semiconductor substrate within the opening portion. “Arranging the organic catalyst in the opening portion” does not prevent the organic catalyst from being arranged outside the opening portion. That is, the organic catalyst may be arranged in a region outside the opening portion of the film that is patterned through the developing step. Such an organic catalyst cannot come into contact with the surface of the semiconductor substrate and thus cannot contribute to the etching reaction.

(9) In a preferred embodiment of the present invention, the step of arranging the organic catalyst may include the steps of applying a photosensitive organic catalyst onto the surface of the semiconductor substrate to form a photosensitive organic catalyst applied film, selectively exposing the photosensitive organic catalyst applied film that is applied on the surface of the semiconductor substrate depending on a position at which the organic catalyst is to be arranged, and developing the exposed photosensitive organic catalyst applied film to obtain a patterned organic catalyst film with the photosensitive organic catalyst film remaining only at the position at which the organic catalyst is to be arranged.

Employing a photosensitive organic catalyst as the organic catalyst allows the photolithography technique to accurately and precisely arrange the organic catalyst only at the position at which the organic catalyst is to be arranged on the surface of the semiconductor substrate.

(10) In a preferred embodiment of the present invention, the step of removing the organic catalyst includes the step of dissolving the organic catalyst with a solvent. The solvent may be one or a mixture of two or more selected from N, N-dimethylformamide (DMF), monoethanolamine (MEA), dimethyl sulfoxide (DMSO), acetonitrile (MeCN), dichloromethane (DCM), 1,2-dimethoxyethane (DME), tetrahydrofuran (THF), propylene glycol monomethyl ether (PGME), propylene glycol monomethyl ether acetate (PGMEA), and N-methyl-2-pyrrolidone (NMP).

These solvents can dissolve and remove the organic catalyst.

(11) In a preferred embodiment of the present invention, the step of removing the organic catalyst includes the step of peeling the organic catalyst with a peeling solution. The peeling solution may employ one or more of sulfuric acid/hydrogen peroxide mixture (SPM) and ozone water (deionized water with O₃ dissolved therein). The peeling solution may be supplied onto the surface of the semiconductor substrate after performing an ozone baking treatment in which the semiconductor substrate is heated in an ozone atmosphere.

(12) In a preferred embodiment of the present invention, the substrate processing method may further include the steps of, after the step of removing the organic catalyst, supplying an oxidizing solution onto the surface of the semiconductor substrate to form an oxidized film, and removing the oxidized film that is formed in the oxidizing step with an etching solution.

Thus adding the oxidizing step and the oxidized film etching step exhibits an advantageous effect that the surface of the structure (holes, trenches, recessed portions, etc.) formed through the etching reaction with the organic catalyst can be smoothed.

(13) The oxidizing solution that is used in the oxidizing step may employ one or two or more of hydrogen peroxide water (H₂O₂), ammonia/hydrogen peroxide mixture (e.g. SC1), hydrochloric acid/hydrogen peroxide mixture (e.g. SC2), and sulfuric acid/hydrogen peroxide mixture (SPM).

(14) The etching solution that is used in the oxidized film etching step may employ, by way of example, dilute hydrofluoric acid (dHF).

(15) The step of supplying the etching solution onto the surface of the semiconductor substrate on which the organic catalyst is arranged may be performed by a method of discharging the etching solution through a nozzle onto the surface of the semiconductor substrate or by a method of immersing the semiconductor substrate in the etching solution.

Any two or more of the foregoing features, particularly the features of (1) to (15), may be combined.

The foregoing and further objects, features, and advantageous effects of the present invention will become apparent from the following Description of Preferred Embodiments with reference to the accompanying drawings.

### BRIEF DESCRIPTION OF DRAWINGS

FIG. 1 is a conceptual view for illustrating a mechanism of etching on a semiconductor substrate according to a preferred embodiment of the present invention.

FIGS. 2A-2G are process charts showing a substrate processing method according to a first preferred embodiment of the present invention.

FIGS. 3(A)-3(C) are schematic views showing step by step etching by an oxidation dissolution reaction.

FIGS. 4A-4F are process charts showing a substrate processing method according to a second preferred embodiment of the present invention.

FIGS. 5A-5I are process charts showing a substrate processing method according to a third preferred embodiment of the present invention.

### DESCRIPTION OF PREFERRED EMBODIMENTS

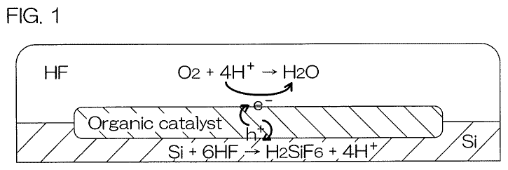

FIG. 1 is a conceptual view for illustrating a mechanism of etching on a semiconductor substrate according to a preferred embodiment of the present invention.

In the case where a silicon substrate is used as the semiconductor substrate and hydrogen fluoride (HF) is used as a corrosive agent in an etching solution by way of example, an oxidation dissolution reaction shown in FIG. 1 occurs on a surface of the silicon substrate on which an organic catalyst is arranged.

The chemical reaction involved in the oxidative dissolution reaction in FIG. 1 includes the following Step 1, Step 2, and Step 3. Oxygen (O₂) dissolved in an aqueous solution of hydrogen fluoride or hydrogen peroxide water (H₂O₂) mixed with an aqueous solution of hydrogen fluoride is here employed as an oxidizing agent in the etching solution by way of example. Other oxidizing agents such as nitric acid (HNO₃), sodium persulfate (Na₂S₂O₈), potassium persulfate (K₂S₂O₈) and the like can be used as the oxidizing agent in the etching solution.

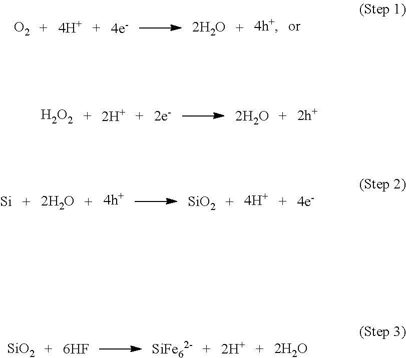

Step 1 is a reduction reaction of the oxidizing agent at the interface between the organic catalyst and the etching solution. The oxidizing agent in the etching solution, such as oxygen (O₂) or hydrogen peroxide (H₂O₂), is reduced by acquiring hydrogen ions (H⁺) in the solution and electrons (e⁻) supplied from the organic catalyst. This causes holes (h⁺) to be produced in the organic catalyst.

Step 2 is an oxidation reaction at the interface between the organic catalyst and the silicon substrate. The holes (h⁺) produced in the organic catalyst through Step 1 rapidly move to the interface with the silicon substrate and oxidize silicon (Si) on the surface of the silicon substrate. That is, silicon is oxidized by acquiring oxygen from water in the solution and acquiring holes (h⁺) from the organic catalyst (i.e. releasing electrons (e⁻) into the organic catalyst). This causes silicon oxide (SiO₂) to be produced.

Step 3 is a dissolution reaction of silicon oxide. Silicon oxide produced on the surface of the silicon substrate is dissolved by the corrosive agent (here, hydrogen fluoride (HF)) in the etching solution and releases hydrogen ions (H⁺) into the solution. The hydrogen ions are used for the reaction in Step 1.

The silicon substrate is etched through cyclic etching in which Step 1, Step 2, and Step 3 are repeated.

The chemical reaction at the interface between the etching solution and the organic catalyst (represented as “A” in the following chemical reaction formula) in Step 1 can be indicated in greater detail as follows.

Oxidizing agent reaction: O₂+4H⁺4e⁻→2H₂O (reduction reaction)

Organic catalyst reaction: 4A-4e⁻→4A⁺+4h⁺ (oxidation reaction)

That is, the oxidizing agent in the etching solution is reduced by acquiring electrons, while the organic catalyst is oxidized by releasing electrons.

On the other hand, the chemical reaction at the interface between the organic catalyst (A) and the silicon substrate in Step 2 can be indicated in greater detail as follows.

Silicon substrate reaction: Si+2H₂O+4h⁺→SiO₂+4H⁺+4e⁻ (oxidation reaction)

Organic catalyst reaction: 4A⁺+4e⁻→4A (reduction reaction)

That is, the silicon substrate is oxidized by releasing electrons, while the organic catalyst is reduced by acquiring electrons.

For Step 1 to occur, it is required that the reduction potential E_{O} of the oxidizing agent be higher than the reduction potential E_{A} of the organic catalyst. Also, for Step 2 to occur, it is required that the reduction potential E_{A} of the organic catalyst be higher than the reduction potential E_{Si} of the silicon substrate.

Accordingly, in this preferred embodiment, the organic catalyst is selected such that the reduction potential E_{A} meets the following condition:

$${E}_{O} > {E}_{A} > {E}_{S i} ( = 0.67 V )$$

Since this also applies when a substrate of a semiconductor material other than silicon is used, the organic catalyst is selected such that the following formula's condition is met that is expressed using the reduction potential E_{S} of such a semiconductor material (E_{S}=E_{Si} in the case of silicon):

$${E}_{O} > {E}_{A} > {E}_{S}$$

More specific preferred embodiments will hereinafter be described.

### <Substrate Processing Method According to a First Preferred Embodiment>

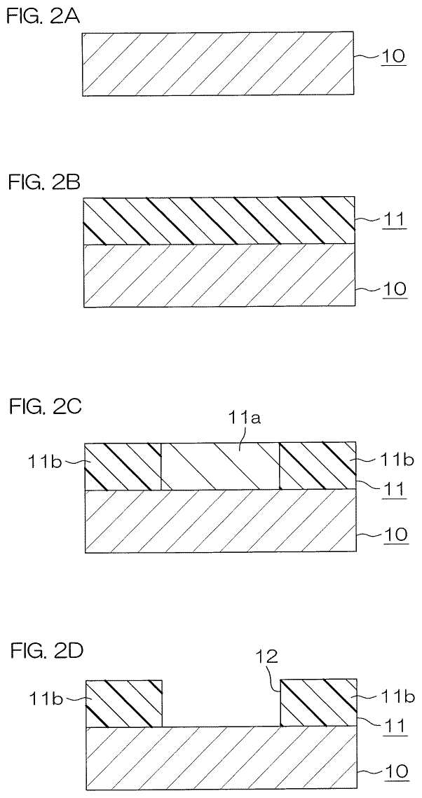

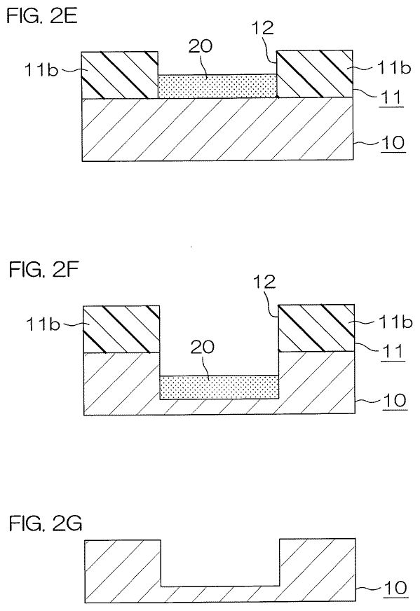

FIGS. 2A to 2G are process charts showing a substrate processing method according to a first preferred embodiment of the present invention.

Referring first to FIG. 2A, a semiconductor substrate 10 to be processed is prepared. The semiconductor substrate 10 can employ a silicon (Si) substrate, a silicon carbide (Sic) substrate, a germanium (Ge) substrate, a III-V compound semiconductor substrate, or the like. The III-V compound semiconductor substrate is a semiconductor substrate made of a compound of a III group element and a V group element and, specifically, a semiconductor substrate made of a III-V group compound such as gallium arsenide (GaAs), indium phosphorus (InP), gallium phosphorus (GaP), or the like.

In this preferred embodiment, the case where the semiconductor substrate 10 employs a silicon substrate (silicon wafer) will be described by way of example. The semiconductor substrate 10 may be referred to as a “silicon wafer 10” below.

Referring to FIG. 2B, an applying step is performed in which a photolithography resin composition is applied onto the surface of the silicon wafer 10 prepared to form an applied film 11. As a method of applying a photolithography resin composition (hereinafter referred to as a “photoresist solution”) onto the surface of the silicon wafer 10, a spin-coating treatment may be employed in which the silicon wafer 10 is held horizontally by a spin chuck and the photoresist solution is dripped from above while the silicon wafer 10 is rotated about a vertical rotation axis that passes through its center, to apply the photoresist solution uniformly on the surface of the silicon wafer 10.

A prebake treatment may then be performed, as an example, in which the silicon wafer 10 is heated at around 100° C. Centigrade to vaporize solvent in the photoresist solution and thereby to cure the applied film 11.

Referring to FIG. 2C, an exposing step is performed in which the applied film 11 is position-selectively exposed. In the exposing step, the applied film 11 is exposed to light irradiation through a photomask (not shown). In the case where a positive photoresist is used, a portion 11a of the applied film that has been exposed to light irradiation shows an increased solubility to the developing solution, while a portion 11b of the applied film that has been protected from light by the photomask shows little variation in the solubility. Hence, if the photomask is selected such that only the portion 11a of the applied film, which covers a region to be etched on the surface of the silicon wafer 10, is exposed to light irradiation, the applied film 11 can be position-selectively exposed. In the case where a negative photoresist is used, it is only required to use a photomask with an inverted pattern thereof.

Referring to FIG. 2D, a developing step is performed in which the exposed applied film 11 is developed to obtain a patterned film 11b. In the developing step, a developing solution is applied to the applied film 11. The developing solution may employ, by way of example, an aqueous solution of tetramethylammonium hydroxide (TMAH). The applied film 11a, which shows an increased solubility as a result of exposure, is dissolved and removed by the developing solution. This results in that the patterned film 11b is obtained on the surface of the silicon wafer 10, the film having an opening portion 12 opened and formed at a position at which an organic catalyst to be described hereinafter is to be arranged. The patterned film 11b is a mask film that masks and protects the surface of the silicon wafer 10 in a region other than the opening portion 12, and thus will hereinafter be referred to as a “mask film 11b.”

In is noted that after the developing step, the surface of the silicon wafer 10 may be rinsed with pure water to stop the development. The applying step, the exposing step, and the developing step are processing steps publicly known in semiconductor manufacturing processes.

Referring to FIG. 2E, an arranging step is performed in which an organic catalyst 20 is arranged in the opening portion 12 of the mask film 11b.

The organic catalyst 20 may employ a redox organic compound or a redox organic polymer. One type of a redox organic compound or one type of a redox organic polymer may be used, or two or more types of a redox organic compound or two or more types of a redox organic polymer may be used. Alternatively, one or more types of a redox organic compound and one or more types of a redox organic polymer may be mixed for use. A redox organic compound and a redox organic polymer both serve as a redox organic catalyst that has reversible and fast electron transfer ability to promote redox reactions.

The redox organic compound may exemplarily employ one or a combination of two or more selected from the redox organic compound group consisting of 2,2,6,6-tetramethylpiperidinyloxyl (TEMPO), 2,5-di-tert-butyl-1,4-bis(2-methoxyethoxy)benzene (DBBB), N-ethylphenothiazine (EPT), and 3,7-bis(trifluoromethyl)-N-ethylphenothiazine (BCF3EPT), and derivatives thereof.

The redox organic polymer may exemplarily employ one or a combination of two or more selected from the redox organic polymer group consisting of TEMPO polymer, Poly(2,2,6,6-tetramethylpiperidinyloxy-4-vinylmethacrylate) (PTMA), Poly(3,4-ethylenedioxythiophene) (PEDOT), and Poly(3-vinyl-N-methylphenothiazine) (PVMPT), and derivatives thereof.

This preferred embodiment specifically shows an example in which a TEMPO derivative that is represented by the following chemical formula is used. It is noted that the redox reaction due to electron transfer and the oxidation-reduction potential E_{O} are shown together.

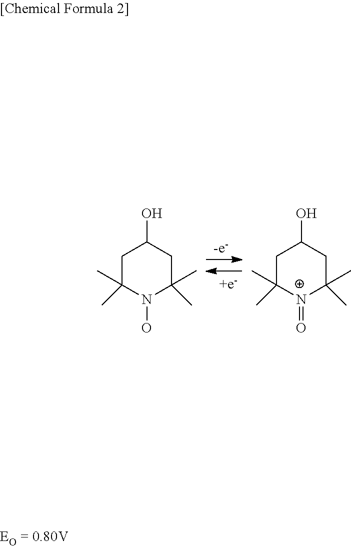

### TEMPO Derivative

The arrangement of the organic catalyst 20 into the opening portion 12 of the mask film 11b may employ, by way of example, a spin-coating treatment or a spin-drying treatment. Specifically, the organic catalyst 20 is dripped from above to be arranged within the opening portion 12 while the silicon wafer 10 is held horizontally by a spin chuck and rotated horizontally. Unnecessary organic catalyst 20 adhering to, for example, the upper surface of the mask film 11b can be removed through a spin-drying treatment in which the silicon wafer 10 is rotated horizontally at high speed. It is noted that unnecessary organic catalyst 20 may be left on the upper surface of the mask film 11b. This is for the reason that the organic catalyst 20 cannot come into contact with the surface of the silicon wafer 10 and thus cannot contribute to the etching reaction. The “arrangement of the organic catalyst 20 into the opening portion 12” means ensuring a state where the organic catalyst 20 can react with the surface of the silicon wafer 10 that is exposed through the opening portion 12 and, typically, means bringing the organic catalyst 20 into contact with the surface of the silicon wafer 10 that is exposed through the opening portion 12. Any organic catalyst 20 may therefore be left on the mask film 11b outside of the opening portion 12.

Referring to FIG. 2F, an etching step is performed in which the mask film 11b is used as a mask and an aqueous solution that contains a corrosive agent and an oxidizing agent is used as an etching solution to etch the silicon wafer 10 in the presence of the organic catalyst 20 so that a hole or a trench is formed in the silicon wafer 10.

The etching step is performed as wet etching in view of etching speed and efficiency.

The etching solution may employ an aqueous solution that contains any one of dissolved oxygen (O₂), ozone (O₃), hydrogen peroxide (H₂O₂), nitric acid (HNO₃), sodium persulfate (Na₂S₂O₈), and potassium persulfate (K₂S₂O₈) as the oxidizing agent, and any one of hydrogen fluoride (HF), buffered hydrofluoric acid (BHF), ammonia, sulfuric acid, hydrochloric acid, and citric acid as the corrosive agent.

In view of elimination of metal elements, it is preferable to use an oxidizing agent other than sodium persulfate (Na₂S₂O₈) and potassium persulfate (K₂S₂O₈) among the oxidizing agent group described above. However, metals (sodium, potassium, etc.) other than noble metals are easily ionized and can be easily removed using an ordinary inexpensive treatment solution, while removal of noble metals is relatively difficult and requires an expensive chemical solution. Accordingly, the use of sodium persulfate (Na₂S₂O₈) or potassium persulfate (K₂S₂O₈) as the oxidizing agent cannot pose any risk of metal contamination or cost problems.

The corrosive agent is preferably selected depending on the semiconductor material that constitutes the semiconductor substrate. Specific examples are as follows. Hydrogen fluoride or buffered hydrofluoric acid is preferred for silicon and silicon carbide. Ammonia, sulfuric acid, hydrochloric acid, or hydrogen fluoride is preferred for germanium. Sulfuric acid is preferred for III-V compound semiconductors. In addition, ammonia or citric acid may be used for gallium arsenide and gallium phosphorus. Further, hydrochloric acid may be used for gallium phosphorus and indium phosphorus.

This preferred embodiment shows an example in which an aqueous solution that contains hydrogen peroxide (H₂O₂) as the oxidizing agent and hydrogen fluoride (HF) as the corrosive agent is used as the etching solution.

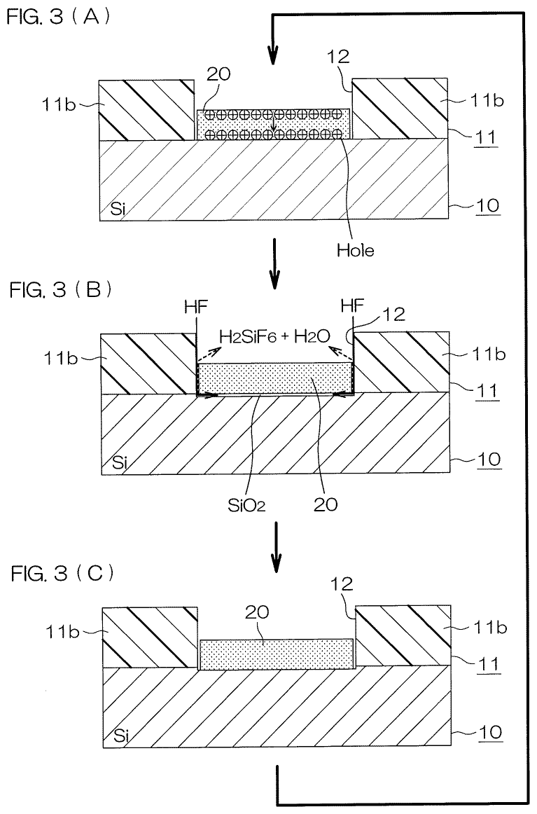

An etching mechanism in the silicon wafer 10 is achieved by the oxidation dissolution reaction as described above with reference to FIG. 1. Etching by the oxidation dissolution reaction can be shown step by step in the schematic views of FIGS. 3(A)-3(C), and etching of the silicon wafer 10 progresses through a cycle of reactions occurring in the order of FIG. 3(A)→FIG. 3(B)→FIG. 3(C)→FIG. 3(A)→ . . . .

The chemical reaction involved in the oxidative dissolution reaction includes the following Step 1, Step 2, and Step 3.

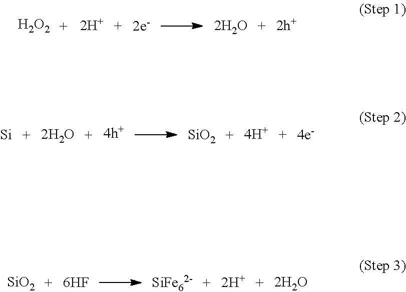

Step 1 is a reduction reaction of the oxidizing agent, in which hydrogen peroxide (H₂O₂) is reduced into water (H₂O) by acquiring hydrogen ions (H⁺) from the aqueous solution (etching solution) and acquiring electrons (e⁻) from the organic catalyst 20, whereby holes (h⁺) are produced in the organic catalyst 20. This is shown in FIG. 3(A).

Step 2 is an oxidation reaction that occurs in the silicon wafer 10 at the interface between the organic catalyst 20 and the silicon wafer 10. The holes (h⁺) produced in the organic catalyst 20 through Step 1 rapidly move to the interface with the silicon wafer 10 and oxidize silicon (Si) on the surface of the silicon wafer 10. That is, silicon is oxidized by acquiring oxygen (O₂) from water (H₂O) in the aqueous solution (etching solution) and acquiring holes (h⁺) from the organic catalyst 20 (i.e. providing electrons (e⁻) to the organic catalyst 20). This causes silicon oxide (SiO₂) to be produced. This is shown in FIG. 3(B).

Step 3 is a dissolution reaction of silicon oxide. Silicon oxide produced on the surface of the silicon wafer 10 is dissolved by hydrogen fluoride (HF) solution and releases hydrogen ions (H⁺) into the aqueous solution (etching solution). The hydrogen ions are used for the reaction in Step 1. This is shown in FIG. 3(C). For example, hydrofluoric acid (HF) enters through the gap between the mask film 11b and the organic catalyst 20, and dissolves SiO₂ produced on the surface side of the silicon wafer 10. This causes the organic catalyst 20 to come into contact with a new surface of the silicon wafer 10, as shown in FIG. 3(C).

The silicon wafer 10 is etched through cyclic etching in which Step 1, Step 2, and Step 3 are repeated.

Referring to FIG. 2G, a removing step is performed in which after performing desired etching on the silicon wafer 10 through the etching step described above, the organic catalyst 20 and the mask film 11b is removed from the silicon wafer 10.

The removing step may employ, by way of example, a dissolving step in which the organic catalyst 20 is dissolved with solvent. The solvent may exemplarily employ mixture of two or more selected from N,N-one or a dimethylformamide (DMF), monoethanolamine (MEA), dimethyl sulfoxide (DMSO), acetonitrile (MeCN), dichloromethane (DCM), 1,2-dimethoxyethane (DME), tetrahydrofuran (THE), propylene glycol monomethyl ether (PGME), propylene glycol acetate (PGMEA), monomethyl ether and N-methyl-2-pyrrolidone (NMP).

While the organic catalyst 20 is dissolved with the solvent described above, the patterned mask film 11b on the surface of the silicon wafer 10 may also be dissolved and removed.

Alternatively, the removing step may be a peeling step in which the organic catalyst 20 is peeled with a peeling solution. The peeling solution may employ an etching solution that is used when etching organic compounds. The peeling solution may employ one or more of sulfuric acid/hydrogen peroxide mixture (SPM) and ozone water (deionized water with O₃ dissolved therein). Prior to supply of the peeling solution, an ozone baking treatment may be performed in which the silicon wafer 10 is heated (e.g. heated to 150° C. or higher) in an ozone atmosphere. That is, for example, sulfuric acid/hydrogen peroxide mixture may be supplied after the ozone baking treatment to peel the organic catalyst 20. Performing the ozone baking treatment allows the consumption of sulfuric acid-hydrogen peroxide water to be reduced and thereby the environmental load to be reduced.

It is noted that if the mask film 11b cannot be removed simultaneously in the peeling step, a step of removing the mask film 11b may be performed separately. For example, the mask film 11b may be removed with a solution such as organic solvent, or ashing may be performed in which the mask film 11b is incinerated and removed by oxidation plasma.

### <Substrate Processing Method According to a Second Preferred Embodiment>

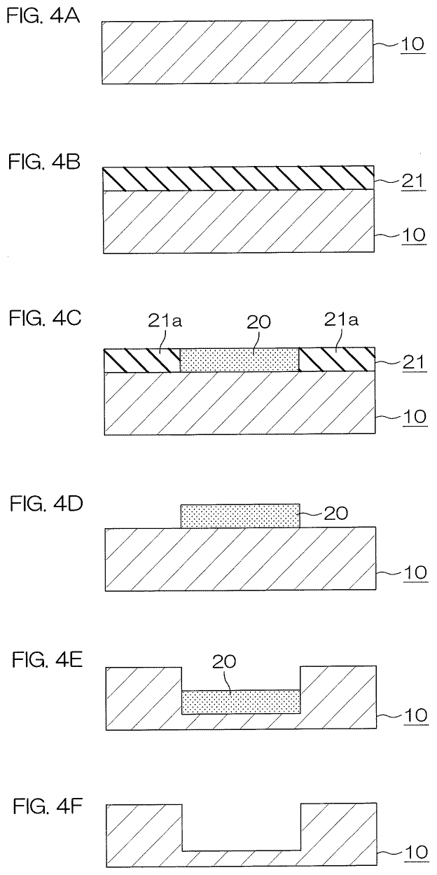

FIGS. 4A to 4F are process charts showing a substrate processing method according to a second preferred embodiment of the present invention.

Referring first to FIG. 4A, a silicon wafer 10 is prepared as a semiconductor substrate 10 to be processed. A semiconductor substrate made of semiconductor material other than silicon may be processed, as is the case in the first preferred embodiment.

Referring to FIG. 4B, an applying step is performed in which a liquid photosensitive organic catalyst (hereinafter referred to as a “photosensitive organic catalyst solution”) is applied onto the surface of the silicon wafer 10 prepared to form an applied film 21. The photosensitive organic catalyst solution may be a mixture of a photoresist solution and an organic catalyst. The organic catalyst may employ a redox organic compound or a redox organic polymer, as is the case in the first preferred embodiment. One or more types of organic catalyst may also be used, as is the case in the first preferred embodiment.

As a method of applying a photosensitive organic catalyst solution onto the surface of the silicon wafer 10, a spin-coating treatment may be employed in which the silicon wafer 10 is held horizontally by a spin chuck and the photosensitive organic catalyst solution is dripped from above while the silicon wafer 10 is rotated about a vertical rotation axis that passes through its center, to apply the solution uniformly on the surface of the silicon wafer 10.

A prebake treatment may also be performed, as an example, in which the silicon wafer 10 is heated at around 100° C. to vaporize solvent in the photosensitive organic catalyst solution and thereby to cure the applied film 21.

Referring to FIG. 4C, an exposing step is performed in which the applied film 21 is position-selectively exposed. In the exposing step, the applied film 21 is exposed to light irradiation through a photomask (not shown). In the case where the photosensitive organic catalyst is a positive photosensitive material (typically, a mixture with a positive photoresist), a portion 21a of the applied film that has been exposed to light irradiation shows an increased solubility to the developing solution, while a portion of the applied film 21 that has been protected from light by the photomask shows little variation in the solubility. Hence, if the photomask is selected such that only the portion 21a of the applied film, which covers a region not to be etched on the surface of the silicon wafer 10, is exposed to light irradiation, the applied film 21 can be position-selectively exposed. In the case where the photosensitive organic catalyst is a negative photosensitive material (typically, a mixture with a negative photoresist), it is only required to use a photomask with an inverted pattern thereof.

Referring to FIG. 4D, a developing step is performed in which the exposed applied film 21 is developed to obtain a patterned film 20. In the developing step, a developing solution is applied to the applied film 21. The developing solution may employ, by way of example, an aqueous solution of tetramethylammonium hydroxide (TMAH). The applied film 21a, which shows an increased solubility as a result of exposure, is dissolved and removed by the developing solution. This results in that the patterned film 20 is left on the surface of the silicon wafer 10. The patterned film 20 is a film that contains the organic catalyst and can be used as an organic catalyst that promotes the etching reaction (redox reaction). Hence, the patterned film 20 will be referred to differently as an “organic catalyst 20” in the following continued description.

Referring to FIG. 4E, an etching step is performed. The organic catalyst 20 that is formed on the surface of the silicon wafer 10 serves as a film that promotes selective etching. That is, the organic catalyst 20 provides etching selectivity to the region in which it is formed, the selectivity causing etching to progress more selectively as compared with the region in which the organic catalyst 20 is not formed. More specifically, when an aqueous solution that contains a corrosive agent and an oxidizing agent is supplied as an etching solution onto the surface of the silicon wafer 10, etching of the silicon wafer 10 rapidly progresses in the presence of the organic catalyst 20 (that is, in the region where the organic catalyst 20 is formed,), while etching of the silicon wafer 10 hardly progresses in the region where the organic catalyst 20 does not exist. The organic catalyst 20 can thus be utilized to selectively etch the silicon wafer 10 and thereby to process the silicon wafer 10 to form a hole or a trench therein.

The etching step is performed as wet etching in view of etching speed and efficiency. Examples of the etching solution that may be employed are the same as those in the first preferred embodiment.

The etching mechanism and the oxidation dissolution reaction in the silicon wafer 10 are the same as those in the substrate processing method described above according to the first preferred embodiment and will not be described to avoid redundancy.

Referring to FIG. 4F, a removing step is performed in which after performing desired etching on the silicon wafer 10 through the etching step, the organic catalyst 20 is removed from the silicon wafer 10. The details of the removing step are the same as

those in the substrate processing method described above according to the first preferred embodiment and will not be described to avoid redundancy.

### <Substrate Processing Method According to a Third Preferred Embodiment>

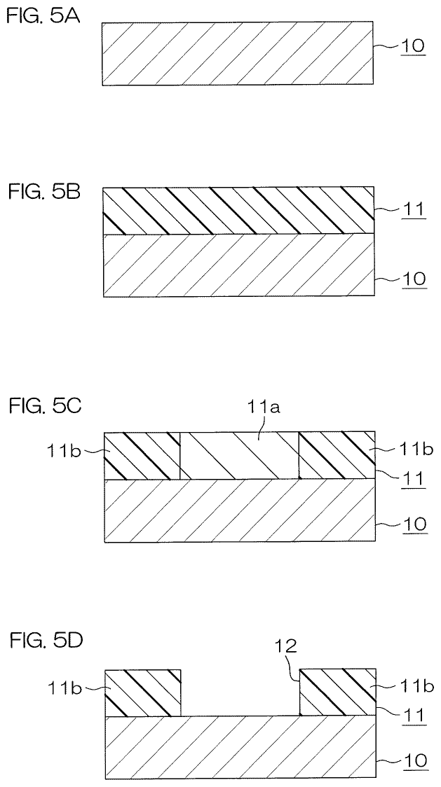

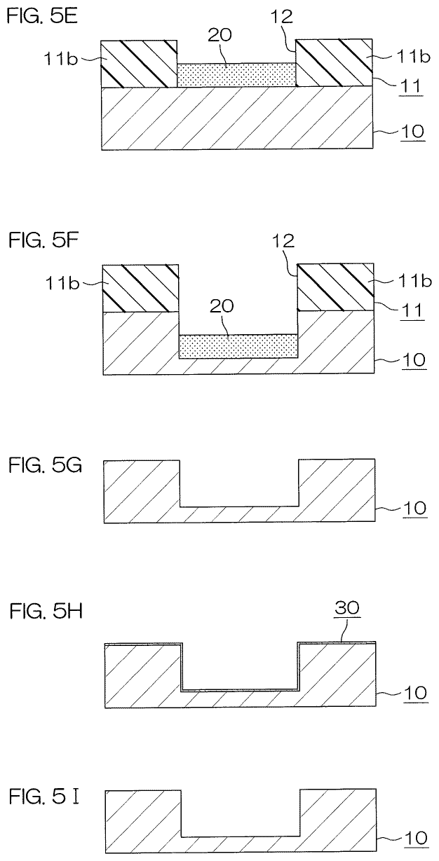

FIGS. 5A to 5I are process charts showing a substrate processing method according to a third preferred embodiment of the present invention.

Referring to FIGS. 5A to 5G, the substrate processing method according to the third preferred embodiment includes a step of preparing a semiconductor substrate (silicon wafer 10) (FIG. 5A), an applying step of forming an applied film 11 (FIG. 5B), an exposing step (FIG. 5C), a developing step (FIG. 5D), an arranging step of arranging an organic catalyst 20 (FIG. 5E), an etching step (FIG. 5F), and a removing step (FIG. 5G), which are the same as those in the substrate processing method according to the first preferred embodiment and will not be described to avoid redundancy.

Referring to FIG. 5H, the substrate processing method according to the third preferred embodiment is characterized by including an oxidizing step in which the surface and the etched site of the silicon wafer 10 after etching are oxidized with an oxidizing solution to form an oxidized film 30. The oxidizing solution may employ one or two more or of hydrogen peroxide water (H₂O₂), ammonia/hydrogen peroxide mixture (e.g. SC1), hydrochloric acid/hydrogen peroxide mixture (e.g. SC2), and sulfuric acid/hydrogen peroxide mixture (SPM).

Also, referring to FIG. 5I, an oxidized film etching step is provided in which the oxidized film 30 formed in the oxidizing step is removed with an etching solution such as dilute hydrofluoric acid (dHF).

Processing the silicon wafer 10 through desired etching to form a desired hole or trench therein, and then covering with an oxidized film the processed surface region of the silicon wafer 10 including the hole or trench, and etching and removing the oxidized film, as in the third preferred embodiment, exhibits an advantageous effect that the processed surface (including a structure such as a hole, a trench, or a recessed portion) of the silicon wafer 10 can be smoothened.

The substrate processing methods according to the first, second, and third preferred embodiments can be applied to semiconductor device manufacturing processes.

One example application is to form an Si through-via electrode (TSV: Through-Silicon Via). A TSV is formed by forming through-hole that is through a silicon substrate (typically, a pre-thinned silicon substrate) and filling the through-hole with an electrode material. The above-mentioned substrate processing methods can be applied in the step of forming a TSV through-hole. Such a TSV may be formed in a silicon substrate such as an LSI (large-scale integrated circuit) substrate with active devices formed therein. In this case, the TSV is used for electrode retrieval to the rear surface of the LSI substrate. Such a TSV may be formed in a silicon substrate such as a rewiring substrate interposed between an integrated circuit chip and a wiring substrate, that is, a so-called interposer.

Another example application is to use in a CMOS (Complementary Metal Oxide Semiconductor) process. For example, the above-mentioned substrate processing methods may be used when a silicon substrate is selectively etched to form a trench structure in order to provide a region isolation structure such as STI (Shallow Trench Isolation). The above-mentioned substrate processing methods may also be used in a step of selectively etching a silicon substrate to form a fin structure for FinFET (Fin Field-Effect Transistor).

In addition to the above, the above-mentioned substrate processing methods may be applied as etching techniques for forming a vertical (perpendicular to the principal surface; the same will apply below) deep hole and/or trench in a semiconductor substrate and forming a vertical high pillar and/or fin in a semiconductor substrate. The above-mentioned substrate processing methods can then be used in place of the MacEtch method in the processing of various semiconductor substrates that has been performed by the MacEtch method. This allows to overcome the problems associated with the MacEtch method, that is, both the risk of metal contamination and the increased cost.

The preferred embodiments of the present invention, which have heretofore been described in detail, are merely specific examples used to clarify the technical details of the present invention. The present invention should not be construed as being limited to these specific examples. The scope of the present invention is limited only by the appended claims.

### REFERENCE SIGNS LIST

10: Semiconductor substrate, silicon wafer
11: Applied film
11a: Applied film with increased solubility
11b: Applied film with no solubility variation, patterned film, mask film
12: Opening portion
20: Organic catalyst, patterned organic catalyst film
21: Applied film
21a: Applied film with increased solubility
30: Oxidized film

1. A substrate processing method of etching a semiconductor substrate comprising:
selectively arranging an organic catalyst for promotion of a redox reaction in a region to be etched on a surface of the semiconductor substrate;
supplying an etching solution that contains a corrosive agent and an oxidizing agent onto the surface of the semiconductor substrate on which the organic catalyst is arranged; and
after performing desired etching on the semiconductor substrate, removing the organic catalyst from the semiconductor substrate.

2. The substrate processing method according to claim 1, wherein the organic catalyst meets the following condition:
E_{O}>E_{A}>E_{S},
where E_{S} represents a reduction potential of the semiconductor substrate, E_{A} represents a reduction potential of the organic catalyst, and E_{O} represents a reduction potential of the oxidizing agent.

3. The substrate processing method according to claim 1, wherein the organic catalyst includes one or two or more types of a redox organic compound and a redox organic polymer.

4. The substrate processing method according to claim 3, wherein
the redox organic compound contains one or a combination of two or more selected from the redox organic compound group consisting of 2,2,6,6-tetramethylpiperidinyloxyl (TEMPO), 2,5-di-tert-butyl-1,4-bis(2-methoxyethoxy)benzene (DBBB), N-ethylphenothiazine (EPT), and 3,7-bis(trifluoromethyl)-N-ethylphenothiazine (BCF3EPT), and derivatives thereof, and
the redox organic polymer contains one or a combination of two or more selected from the redox organic polymer group consisting of TEMPO polymer, Poly(2,2,6,6-tetramethylpiperidinyloxy-4-vinylmethacrylate) (PTMA), Poly(3,4-ethylenedioxythiophene) (PEDOT), and Poly(3-vinyl-N-methylphenothiazine) (PVMPT), and derivatives thereof.

5. The substrate processing method according to claim 1, wherein the organic catalyst contains a TEMPO derivative that is represented by the following chemical formula:

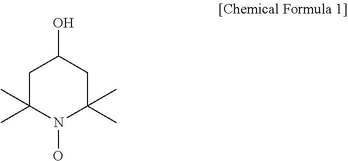

6. The substrate processing method according to claim 1, wherein the etching solution contains:
one or more of dissolved oxygen (O₂), ozone (O₃), hydrogen peroxide (H₂O₂), nitric acid (HNO₃), sodium persulfate (Na₂S₂O₈), and potassium persulfate (K₂S₂O₈) as the oxidizing agent; and
one or more of hydrogen fluoride (HF), buffered hydrofluoric acid (BHF), ammonia, sulfuric acid, hydrochloric acid, and citric acid as the corrosive agent.

7. The substrate processing method according to claim 1, wherein the semiconductor substrate is a silicon substrate, a silicon carbide substrate, a germanium substrate, or a III-V compound semiconductor substrate.

8. The substrate processing method according to claim 1, wherein arranging the organic catalyst includes:
applying a photolithography resin composition onto the surface of the semiconductor substrate to form an applied film;
selectively exposing the applied film that is applied on the surface of the semiconductor substrate depending on a position at which the organic catalyst is to be arranged;
developing the exposed applied film to obtain, on the surface of the semiconductor substrate, a patterned film that has an opening portion at the position at which the organic catalyst is to be arranged; and
arranging the organic catalyst in the opening portion.

9. The substrate processing method according to claim 1, wherein arranging the organic catalyst includes:
applying a photosensitive organic catalyst onto the surface of the semiconductor substrate to form a photosensitive organic catalyst applied film;
selectively exposing the photosensitive organic catalyst applied film that is applied on the surface of the semiconductor substrate depending on a position at which the organic catalyst is to be arranged; and
developing the exposed photosensitive organic catalyst applied film to obtain a patterned organic catalyst film with the photosensitive organic catalyst film remaining only at the position at which the organic catalyst is to be arranged.

10. The substrate processing method according to claim 1, wherein
removing the organic catalyst includes the step of dissolving the organic catalyst with a solvent, and
the solvent contains one or two or more selected from N,N-dimethylformamide (DMF), monoethanolamine (MEA), dimethyl sulfoxide (DMSO), acetonitrile (MeCN), dichloromethane (DCM), 1,2-dimethoxyethane (DME), tetrahydrofuran (THF), propylene glycol monomethyl ether (PGME), propylene glycol monomethyl ether acetate (PGMEA), and N-methyl-2-pyrrolidone (NMP).

11. The substrate processing method according to claim 1, wherein
removing the organic catalyst includes peeling the organic catalyst with a peeling solution, and
the peeling solution contains one or more of sulfuric acid/hydrogen peroxide mixture (SPM) and ozone water.

12. The substrate processing method according to claim 1, further comprising:
after removing the organic catalyst, supplying an oxidizing solution onto the surface of the semiconductor substrate to form an oxidized film; and
removing the oxidized film with an etching solution.

13. The substrate processing method according to claim 12, wherein the oxidizing solution contains one or two or more of hydrogen peroxide water (H₂O₂), ammonia/hydrogen peroxide mixture, hydrochloric acid/hydrogen peroxide mixture, and sulfuric acid/hydrogen peroxide mixture (SPM).

14. The substrate processing method according to claim 12, wherein the etching solution for removing the oxidized film contains dilute hydrofluoric acid (dHF).
